(19) United States
(12) Patent Application Publication
(10) Pub. No.: US 2009/0283916 A1
(43) Pub. Date: Nov. 19, 2009

(54) CHIP STRUCTURE AND METHOD OF REWORKING CHIP

(75) Inventor: Ping-Chang Wu, Hsinchu County (TW)

Correspondence Address: J C PATENTS, 4 VENTURE, SUITE 250, IRVINE, CA, 92618, US

(73) Assignee: UNITED MICROELECTRONICS CORP., Hsinchu (TW)

(21) Appl. No.: 12/119,709

(22) Filed: May 13, 2008

(51) Int. Cl. H01L 23/538; H01L 21/00

(52) U.S. Cl. 257/777; 438/4; 257/E21.001; 257/E23.169

(57) ABSTRACT

A method of reworking a chip includes providing a first chip and a second chip. The first and second chips have at least one first module and at least one second module, respectively. The first and second modules electrically connect with each other. The first module of the first chip has a defect. The second module of the second chip has a defect. The first module having a defect of the first chip is opened with the second module of the first chip, and the second module having a defect of the second chip is opened with the first module of the second chip. The first and second chips are stacked, and the second module of the first chip is electrically connects with the first module of the second chip.

### BACKGROUND OF THE INVENTION

1. Field of Invention

The present invention relates to a chip structure and a method of reworking a chip. More particularly, the present invention relates to a chip structure and a method of reworking a chip, wherein the yield is enhanced.

2. Description of Related Art

The continuous miniaturization of semiconductor devices is a main trend in the rapidly developing semiconductor industry for the purpose of not only obtaining smaller sizes, lighter weights and compact designs but also achieving higher functions. Due to the miniaturization of devices, the increase of a wafer area and the production yield, the fabrication of different circuits on a single chip is achievable in an imminent future. The system on chip (SOC) basically relies on a chipset for realizing the disposition of a system on a single chip for the single chip to have the function of the previous chipset.

However, as the demands for a product's functions continue to increase, the design of a system chip becomes more complicated. The complicated design normally leads to the problem of low production yield. For example, in a fabrication process, a chip normally includes a plurality of modules. When one or several of the modules have a defect, the chip is considered as a bad chip. Hence, any chip that has only one or several defective modules, that chip is considered as a bad chip and is discarded. As a result, the production yield is low and the production cost is high.

### SUMMARY OF THE INVENTION

The present invention is to provide a method of reworking a chip to increase production yield.

The present invention is to provide a chip structure to lower the production cost.

According to a method of reworking a chip of the present invention, a first chip and a second chip are provided, wherein the first chip and the second chip respectively includes at least a first module and a second module, and the first and the second modules are electrically connected. Further, the first module of the first chip has a defect, and the second module of the second chip has a defect. Then, an open circuit is created respectively between the defective first module of the first chip and the second module of the first chip, and between the defective second module of the second chip and the first module of the second chip. The first chip and the second chip are further stacked together, wherein the second module of the first chip electrically connects with first module of the second chip.

In accordance to an embodiment of the present invention, the second module of the first chip electrically connects with first module of the second chip by through-silicon via (TSV) or interconnect.

In accordance to an embodiment of the present invention, the open circuit being respectively created between the defective first module of the first chip and the second module of the first chip, and between the defective second module of the second chip and the first module of the second chip is achieved by closing a switch.

In accordance to an embodiment of the present invention, the switch includes a fuse.

In accordance to an embodiment of the present invention, the fuse includes a copper fuse, an aluminum fuse or an e-fuse.

The present invention also provides a chip structure, wherein a process in which the chip structure is applicable includes a packaging process.

According to the present invention, by stacking a plurality of bad chips and using lines to electrically connect the defect-free modules from each of the bad chips, these bad chips are combined to form an operable normal chip.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a schematic cross-sectional view showing selected steps for the method of reworking a chip according to an embodiment of the present invention.

FIG. 2 is a schematic diagram showing the chip structure according to an embodiment of the present invention.

FIG. 3 is a schematic diagram showing the chip structure according to an embodiment of the present invention.

FIG. 4 is a schematic diagram of a chip structure according to another embodiment of the present invention.

FIG. 5 is a schematic diagram of a chip structure according to another embodiment of the present invention.

### DESCRIPTION OF EMBODIMENTS

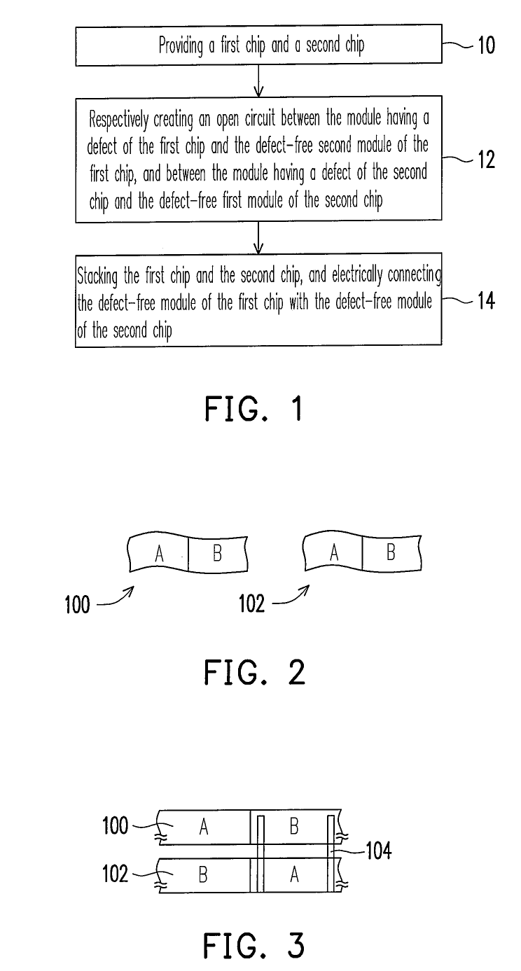

FIG. 1 is a flow diagram of steps of an exemplary method of reworking a chip according to an embodiment of the present invention. FIG. 2 is a schematic diagram of a chip structure according to an embodiment of the present invention. FIG. 3 is a schematic cross-sectional view of a chip structure according to an embodiment of the present invention. More particularly, in the following embodiments, the module on the chip may include a memory module, a CLK (clock) module, a field-programmable gate array (FPGA) module, an input/output (I/O) module or a digital signal processor (DSP) module.

Referring concurrently to FIGS. 1, 2 and 3, in step 10, a first chip and a second chip are provided, wherein the first chip and the second chip are diced from a same wafer. Accordingly, the first chip and the second chip are completely different chips. The first chip and the second chip respectively include a plurality of different modules, wherein each module has its own particular function. In this embodiment of the invention, each of the first chip and the second chip has two modules, wherein one of the two modules is a memory module. As shown in FIG. 2, the first chip 100 and the second chip 102 respectively include modules A and B, wherein module A and module B are electrically connected, and module A (memory module) of the first chip 100 has a defect and module B (memory module) of the second chip 102 also has a defect. Conventionally, the first chip 100 and the second chip 102 are normally being considered as bad chips.

In step 12, an open circuit is created between the module A having a defect of the first chip 100 and the module B of the first chip 100; and similarly, an open circuit is created between the module B having a defect of the second chip 102 and module A of the second chip 102. The opening circuit created between the above module A and module B is accomplished by closing a switch, for example, and the switch may include a fuse, such as a copper fuse, an aluminum fuse or an e-fuse. In other words, in step 12, the open circuit between the module A and module B is achieved by burning the fuse. In other embodiments, a switch may include devices having the above function.

Then, in step 14, the first chip 100 and the second chip 102 are stacked together and module B of the first chip 100 is electrically connected with module A of the second chip 102. As shown in FIG. 3, the method of electrically connecting module B of the first chip 100 and module A of the second chip 102 include the application of through-silicon via (TSV). In another embodiment (not shown), module B of the first chip 100 and module A of the second chip 102 are electrically connected through the application of interconnect. More particularly, in step 14, the first chip 100 and the second chip 200 are stacked, and the defect-free module B of the first chip 100 is electrically connected with the defect-free module A of the second chip 200. Hence, the two bad chips form a chip with a defect-free module A and a defect-free module B to increase the production yield (increase from 0% to 100%) and to lower the production cost.

It is worthy to note that, although the chip of the above embodiment includes two modules, the chip of the invention may include three or more modules in other embodiments. The following disclosure illustrates the method of reworking a chip based on a chip having four modules.

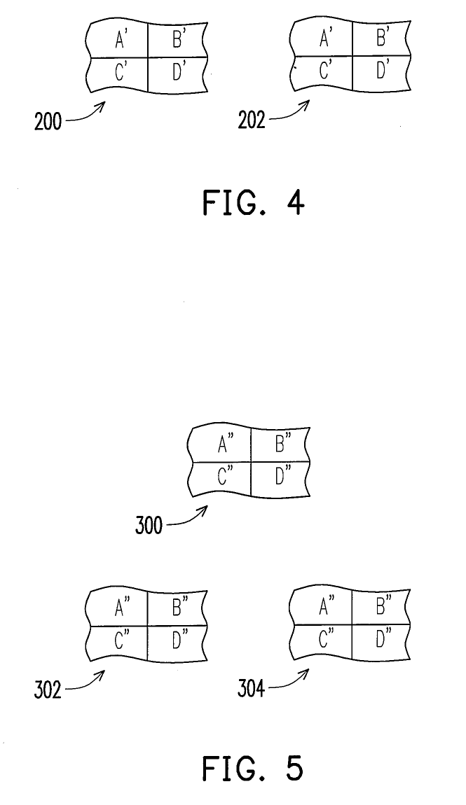

FIG. 4 is a schematic diagram of a chip structure according to another embodiment of the present invention. Referring to FIG. 4, the first chip 200 and the second chip 202 respectively include modules A′, B′, C′ and D′, and the relationship in electrical connection between the modules A′, B′, C′ and D′ is that modules A′, B′, C′ and D′ are electrically connected to each other. In another embodiment, modules A′, B′, C′ and D′ may have other types of relationships in electrical connection. In the first chip 200, modules A′ and D′ have defects, and in the second chip 202, modules B′ and C′ have defects. Accordingly, both the first and the second chips 200, 202 are normally being considered as bad chips. Thereafter, using a fuse as a switch, for example, an open circuit is created between the defective modules A′ and D′ of the first chip 200 and the modules B′ and C′ of the first chip 200, and between the defective modules B′ and C′ of the second chip 202 and the modules A′ and D′ of the second chip 202. Then, the first chip 200 and the second chip 202 are stacked together and by using, for example, through silicon via or interconnect, and the modules B′ and C′ of the first chip are electrically connected with the modules A′ and D′ of the second chip. In other words, by electrically connecting the defect-free modules B′ and C′ in the first chip 200 with the defect-free modules A′ and D′ in the second chip 202, the two bad chips form a chip with the defect-free modules A′, B′, C′ and D′.

The present invention is also applicable to chips with more defective modules, and the process of reworking is similar to the disclosure above and will not be further reiterated herein.

In the aforementioned two embodiments, a defect-free chip is formed with two bad chips being stacked together and electrically re-arranged or reworked. If two bad chips are inadequate to form a defect-free chip, three or more bad chips may be used. The following disclosure illustrates the method of reworking a chip using three bad chips.

FIG. 5 is a schematic diagram of a chip structure according to another embodiment of the present invention. Referring to FIG. 5, a first chip 300, a second chip 304 and a third chip 304 respectively include modules A″, B″, C″, and D″, and the electrical connection between the modules A″, B″, C″, and D″ is that modules A″, B″, C″, and D″ are electrically connected to each other. In another embodiment, modules A′, B′, C′ and D′ may have other types of electrical connection. In the first chip 300, modules A″, B″, and C″ have some defects, and in the second chip 302, modules C″ and D″ have some defects, and in third chip, modules A″, B″ and D″ have some defects. Conventionally, the first, the second and the third chips are considered as bad chips. Thereafter, using a fuse as a switch, for example, an open circuit is created between the defective modules A″, B″, and C″ of the first chip 200 and the module D″ of the first chip 300, and an open circuit is created between the defective modules D″ of the second chip 302 and the modules A″ and B″ of the second chip 302. Similarly, using a fuse as a switch, the defective module D″ of the third chip 304 become opened with the module C″ of the third chip. Thereafter, the first chip 300, the second chip 302 and the third chip 304 are stacked. Further, the module D″ of the first chip 300 and the modules A″ and B″ of the second chip 302 are electrically connected by through silicon via or interconnect. Similarly, the module D″ of the first chip 300 and the module C″ of the third chip 304 are electrically connected. In other words, the first chip 300 not excluding the defective module D″, and the second chip 302 excluding the defective module A″ and B″ are electrically connected; and the first chip excluding the defective module D″ and the third chip excluding the defective module C″ are electrically connected for the three bad chips to form a chip having the modules A″, B″, C″, and D″ that are defect free.

According to the present invention, by stacking a plurality of bad chips together and connecting the required defect-free modules from each chip using a line, the plurality of chips having defects together form a normal and operable chip. Hence, the production yield is increased and the cost is decreased.

More particularly, the method of reworking of the invention is applicable to bad chip with defect, and is also applicable to a normal chip with a defect generated during the fabrication process.

In the following example, the method of reworking of the invention is applied to a plurality of normal chips that are electrically connected and stacked. The dispositions of the modules of the normal chips may be similar to those disclosed in the above embodiments. During the fabrication period, a stacked structure may result with a defect being generated on a normal chip due to various reasons. For example, during the packaging process, it is highly possible to generate a defect on the top-most and the bottom-most chip layer (for example, the memory modules on the top-most and the bottom-most chip layer are generated with defects). Since the chips in a stacked structure are electrically connected using lines, when a defect is generated on one of the chips, the entire structure may become inoperable to lower the yield and to increase the cost. Hence, similar to the previous embodiments, a switch (for example, an e-fuse) is used to created an open circuit between the defective module in the bad chip and the defect-free modules, and the defect-free modules in the bad chip are electrically connected with the normal chip layer above or below. Accordingly, the entire stacked structure would not become inoperable due to just some of the chips being defective.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method of reworking a chip, the method comprising:
providing a first chip and a second chip, the first chip and the second chip respectively comprising at least a first module and a second module, and each of the first modules electrically connecting with each of the second modules, wherein the first module of the first chip comprises a first defect, and the second module of the second chip comprises a second defect;
respectively creating an open circuit between the first module comprising the first defect of the first chip and the second module of the first chip, and between the second module comprising the second defect of the second chip and the first module of the second chip; and
stacking the first chip and the second chip together, wherein the second module of the first chip electrically is connected with first module of the second chip.

2. The method of claim 1, wherein the second module of the first chip is electrically connected with first module of the second chip by a through-silicon via or an interconnect.

3. The method of claim 1, wherein the step of creating the open circuit between the first module comprising the first defect of the first chip and the second module of the first chip, and between the second module comprising the second defect of the second chip and the first module of the second chip comprises closing a switch.

4. The method of claim 3, wherein the switch comprises a fuse.

5. The method of claim 4, wherein the fuse comprises a copper fuse, an aluminum fuse or an e-fuse.

6. The method of claim 1, wherein the first module of the first chip comprises a memory module, and the second module of the first chip comprises at least one of a CLK (clock) module, a field-programmable gate array module, an input/output module, and a digital signal processor module.

7. The method of claim 1, wherein the first module of the second chip comprises at least one of a CLK (clock) module, a field-programmable gate array module, an input/output module, and a digital signal processor module, and the second module of the second chip comprises a memory module.

8. A chip structure, comprising:
a first chip and a second chip being stacked together, the first chip and the second chip respectively comprising at least a first module and a second module, wherein the first module of the first chip comprises a first defect, and the second module of the second chip comprises a second defect, and an opening circuit is created between the first module of the first chip and the second module of the first chip, and between the first module of the second chip and the second module of the second chip; and
a line, electrically connecting the second chip of the first chip and the first chip of the second chip.

9. The chip structure of claim 8, wherein the line comprises a through-silicon via or an interconnect.

10. The chip structure of claim 8, wherein the first module of the first chip comprises a memory module, and the second module of the first chip comprises at least one of a CLK (clock) module, a field-programmable gate array module, an input/output module, and a digital signal processor module.

11. The chip structure of claim 8, wherein the first module of the second chip comprises at least one of a CLK (clock) module, a field-programmable gate array module, an input/output module, and a digital signal processor module, and the second module of the second chip comprises a memory module.

12. A method of reworking a chip, wherein the method is applicable to a plurality of chips comprising at least a first chip and a second chip, and the plurality of chips are electrically connected and stacked, the plurality of chips respectively comprise at least a first module and a second module, and each of the first modules electrically connects with each of the second modules, the method comprising:
performing a process on the plurality of chips, wherein during the process, the first module of at least the first chip generates a defect;
creating an open circuit between the first module with the defect of the first chip and the second module of the first chip; and
electrically connecting the second module of the first chip with the first module of the second chip above or below the first chip.

13. The method of claim 12, wherein the step of creating the open circuit between the first module having the defect of the first chip and the second module of the first chip comprises closing a switch.

14. The method of claim 13, wherein the switch comprises a fuse.

15. The method of claim 14, wherein the fuse comprises an e-fuse.

16. The method of claim 12, wherein the process comprises a packaging process.

17. The method of claim 12, wherein the first module of the first chip comprises a memory module, and the second module of the first chip comprises at least one of a CLK (clock) module, a field-programmable gate array module, an input/output module, and a digital signal processor module.
